(19) United States
(12) Patent Application Publication
(10) Pub. No.: US 2025/0301792 A1
(43) Pub. Date: Sep. 25, 2025

(54) DISPLAY DEVICE AND TILED DISPLAY INCLUDING THE SAME

(71) Applicant: Samsung Display Co., LTD., Yongin-si (KR)

(72) Inventors: Chan Hyun PARK, Yongin-si (KR); Min Seok KIM, Yongin-si (KR); Ki Hoon HA, Yongin-si (KR)

(21) Appl. No.: 18/946,759

(22) Filed: Nov. 13, 2024

(30) Foreign Application Priority Data
Mar. 25, 2024 (KR) 10-2024-0040165

(51) Int. Cl. H01L 27/12; H01L 25/075; H01L 33/62

(52) U.S. Cl. CPC H10D 86/60; H01L 25/0753; H10D 86/443; H10H 20/857

(57) ABSTRACT

A display device according to one or more embodiments includes a substrate including a display area, and a first edge area at one side of the display area, a pixel above the substrate in the display area, a data line in a first conductive layer above the substrate in the first edge area, and a common power line including a first line layer in a second conductive layer above the substrate in the first edge area, the first line layer including a first portion between the display area and the data line, and a second portion spaced from the first portion in a first direction to define an opening therebetween, the opening overlapping the data line.

### CROSS-REFERENCE TO RELATED APPLICATION

The present application claims priority to and the benefit of Korean Patent Application No. 10-2024-0040165, filed on Mar. 25, 2024, in the Korean Intellectual Property Office, the entire disclosure of which is incorporated herein by reference.

### BACKGROUND

### 1. Field

Embodiments of the present disclosure relate to a display device, and a tiled display including the same.

### 2. Description of the Related Art

As the information-oriented society evolves, various demands for display devices are ever increasing. Accordingly, a variety of types of display devices, including light-emitting display devices, are under development.

### SUMMARY

Aspects of the present disclosure provide a display device that can reduce or prevent the likelihood of short circuit defects between lines, and a tiled display including the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate including a display area, and a first edge area at one side of the display area, a pixel above the substrate in the display area, a data line in a first conductive layer above the substrate in the first edge area, and a common power line including a first line layer in a second conductive layer above the substrate in the first edge area, the first line layer including a first portion between the display area and the data line, and a second portion spaced from the first portion in a first direction to define an opening therebetween, the opening overlapping the data line.

The first edge area may extend in a second direction crossing the first direction, wherein the first portion, the second portion, and the data line extend in the second direction.

The substrate may further include a second edge area that meets the first edge area at an end of the first edge area, and that extends in the first direction, wherein the first line layer further includes a third portion connecting the first portion with the second portion in the second edge area.

The third portion may extend in the first direction.

The first line layer may further include a fourth portion connecting the first portion with the second portion across the opening in the first edge area.

The pixel may include a sub-pixel including a pixel circuit including a thin-film transistor, and a light-emitting element connected to the pixel circuit.

The sub-pixel may further include connection electrodes in source conductive layers above the thin-film transistor, a first electrode pad above the connection electrodes, and connected between the connection electrodes and a first contact electrode of the light-emitting element, and a second electrode pad above the connection electrodes, and connected between the common power line and a second contact electrode of the light-emitting element.

The first conductive layer may be one of the source conductive layers, wherein one of the connection electrodes and the data line are in a same layer.

The first electrode pad may include a first pixel electrode above the connection electrodes, and a first transparent electrode above the first pixel electrode, wherein the second electrode pad includes a second pixel electrode above the connection electrodes apart from the first pixel electrode, and a second transparent electrode above the second pixel electrode.

The second conductive layer may be a transparent conductive layer in which the first transparent electrode and the second transparent electrode are located, wherein the first line layer, the first transparent electrode, and the second transparent electrode are in a same layer.

The first line layer and the second transparent electrode may be integral with each other.

The common power line may further include a second line layer below the first line layer, and overlapping the first portion of the first line layer.

The second line layer, the first pixel electrode, and the second pixel electrode may be spaced apart in a same layer.

The second conductive layer may be above the first conductive layer.

The display device may further include a planarization layer between the first conductive layer and the second conductive layer, and covering the first conductive layer.

The planarization layer may include an end covering the data line in the first edge area, wherein the opening of the first line layer is in an open area where the end of the planarization layer and the data line are located.

The first line layer might not overlap the data line in a thickness direction of the substrate.

The display device may further include conductive layers above the substrate, and including the first conductive layer and the second conductive layer, wherein the first conductive layer is at a top of the conductive layers, and includes a transparent conductive material.

The second portion may be between the data line and an end of the first edge area, and is at an outermost position of lines in the first edge area.

According to an aspect of the present disclosure, there is provided a tiled display including display devices, at least one of the display devices including a substrate including a display area, and a first edge area at one side of the display area, a pixel above the substrate in the display area, a data line in a first conductive layer above the substrate in the first edge area, and a common power line including a first line layer in a second conductive layer above the substrate in the first edge area, wherein the first line layer includes a first portion between the display area and the data line, and a second portion spaced from the first portion in a first direction to define an opening therebetween, the opening overlapping the data line.

According to embodiments of the present disclosure, it is possible to reduce or prevent the likelihood of short circuit defects between lines in a display device, and a tiled display including the same. Accordingly, electrical stability of the display device and the tiled display including the same can be ensured, and the reliability can be increased.

However, aspects according to the embodiments of the present disclosure are not limited to those described above, and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a perspective view of a display device according to one or more embodiments of the present disclosure.

FIG. 2 is a perspective view showing the display device according to one or more embodiments of the present disclosure.

FIG. 3 is a plan view showing a pixel according to one or more embodiments of the present disclosure.

FIG. 4 is a plan view showing a pixel according to one or more embodiments of the present disclosure.

FIG. 5 is a plan view showing a display area according to one or more embodiments of the present disclosure.

FIG. 6 is a cross-sectional view showing a display panel according to one or more embodiments of the present disclosure.

FIG. 7 is a plan view showing a tiled display according to one or more embodiments of the present disclosure.

FIG. 8 is a plan view showing a tiled display according to one or more p embodiments of the present disclosure.

FIG. 9 is a plan view showing in detail seams of a tiled display according to one or more embodiments.

FIG. 10 is a plan view showing lines located at an edge of a display device according to one or more embodiments.

FIG. 11 is a plan view showing a first line layer of a common power line according to one or more embodiments.

FIG. 12 is a plan view showing a first line layer of a common power line according to one or more embodiments.

FIG. 13 is a plan view showing area A3 of FIG. 10 in detail.

FIG. 14 is a cross-sectional view showing a display panel according to one or more embodiments of the present disclosure.

FIG. 15 is a cross-sectional view showing a display panel according to one or more embodiments of the present disclosure.

FIG. 16 is a plan view showing lines located at an edge of a display device according to one or more embodiments.

FIG. 17 is a plan view showing a first line layer of a common power line according to one or more embodiments.

FIG. 18 is a plan view showing a first line layer of a common power line according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and

similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

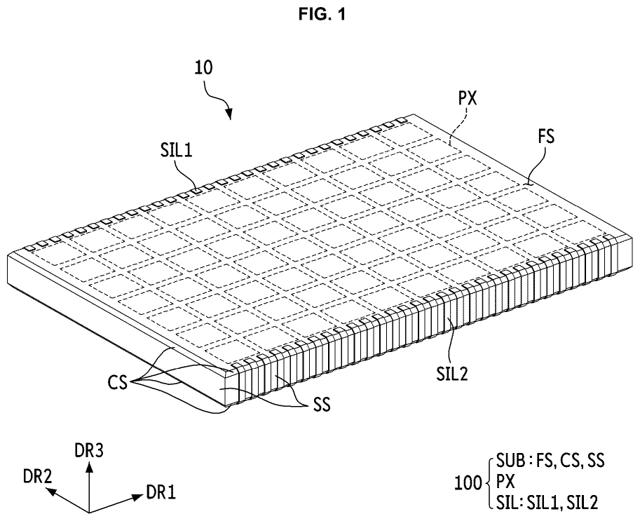

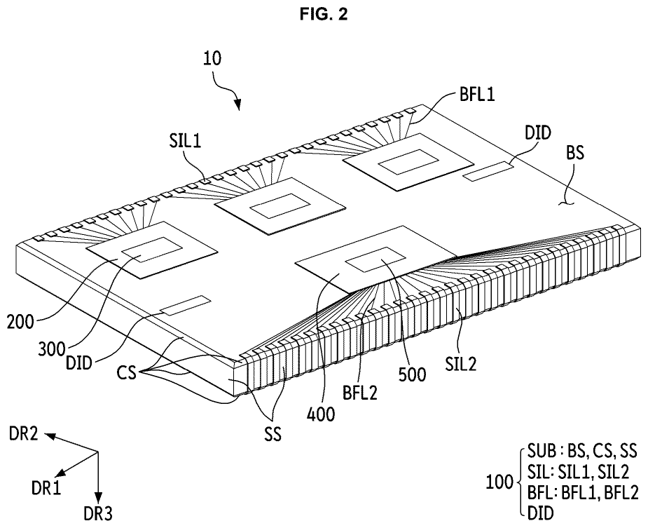

FIG. 1 is a perspective view of a display device according to one or more embodiments of the present disclosure. FIG. 2 is a perspective view showing the display device according to one or more embodiments of the present disclosure. For example, FIGS. 1 and 2 are perspective views showing the front and rear sides of a display device 10, respectively.

Referring to FIGS. 1 and 2, a display device 10 according to one or more embodiments of the present disclosure is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard, and the Internet of Things device.

The display device 10 may include a display panel 100, a first circuit board 200, a source driver circuit 300, a second circuit board 400, and a power supply circuit 500. According to one or more embodiments of the present disclosure, the display device 10 may include a plurality of first circuit boards 200 and a plurality of source driver circuits 300. According to one or more embodiments of the present disclosure, the first circuit boards 200, the source driver circuits 300, a second circuit board 400, and a power supply circuit 500 may be located on the rear surface of the display panel 100.

The display panel 100 may include a substrate SUB, pixels PX, side lines SIL, and back face lines BFL. According to one or more embodiments of the present disclosure, the display panel 100 may further include device identifiers DID.

The substrate SUB may include a first surface FS, a second surface BS, and side surfaces SS. The first surface FS and the second surface BS of the substrate SUB may face each other. For example, the first surface FS may be the front surface of the substrate SUB, and the second surface BS may be the rear surface, or back surface, of the substrate SUB. According to one or more embodiments of the present disclosure, the substrate SUB may further include chamfered surfaces CS located between the first and second surfaces FS and the side surfaces SS.

According to one or more embodiments of the present disclosure, the substrate SUB may have a substantially rectangular shape on a plane defined by a first direction DR1 and a second direction DR2. According to one or more embodiments of the present disclosure, the first direction DR1 may be the horizontal direction or the longer-side direction of the substrate SUB, and the second direction DR2 may be the vertical direction or the shorter-side direction of the substrate SUB. The substrate SUB may have a thickness in a third direction DR3 that crosses (e.g., that is orthogonal to) the first direction DR1 and the second direction DR2.

When the substrate SUB has a generally rectangular plate shape, the substrate SUB may include four side surfaces SS, and eight chamfered surfaces CS located between each of the first surface FS and the second surface BS of the substrate SUB and the four side surfaces SS. The chamfered surfaces CS may refer to faces that are chamfered obliquely at the boundaries between the first surface FS of the substrate SUB and the side surfaces SS, and between the second surface BS of the substrate SUB and the side surfaces SS, to reduce or prevent the likelihood of chipping defects in the side lines SIL. Due to the chamfered surfaces CS, the bending angle of each of the side lines SIL may become gentle. Accordingly, it is possible to reduce or prevent the likelihood of chipping or cracks from occurring in the side lines SIL.

The shape of the substrate SUB is not limited to the above. For example, the substrate SUB may have various shapes depending on embodiments.

The pixels PX may be located on the first surface FS of the substrate SUB to display images. The pixels PX may be arranged in a matrix in the first direction DR1 and the second direction DR2, but the arrangement of the pixels PX is not limited thereto.

The side lines SIL may include first side lines SIL1 and second side lines SIL2 located on different side surfaces of the substrate SUB. As an example, the side lines SIL may include first side lines SIL1 located on a side surface SS of the substrate SUB located at the upper end of the substrate SUB in the second direction DR2, and second side lines SIL2 located on the other side surface SS of the substrate SUB located at the lower end of the substrate SUB in the second direction DR2.

For example, the first side lines SIL1 may be located on the first surface FS, the second surface BS, one side surface SS (e.g., the upper surface), and two chamfered surfaces CS located between the one side surface SS and each of the first surface FS and the second surface BS of the substrate SUB. The second side lines SIL2 may be located on the first surface FS, the second surface BS, one side surface SS (e.g., the lower surface), and two chamfered surfaces CS located between the one side surface SS and each of the first surface FS and the second surface BS of the substrate SUB.

The first side lines SIL1 may connect first pads (e.g., upper pads of the display panel 100) located on the first surface FS of the substrate SUB with first back face lines BFL1 (e.g., first back face fan-out lines) located on the second surface BS of the substrate SUB. The second side lines SIL2 may connect second pads (e.g., lower pads of the display panel 100) located on the first surface FS of the substrate SUB with second back face lines BFL2 (e.g., second back face fan-out lines) located on the second surface BS of the substrate SUB. The first pads and the second pads may be referred to as front pads of the display panel 100. The first pads may be located on the first surface FS of the substrate SUB, and may be connected to data lines connected to the pixels PX. The second pads may be located on the first surface FS of the substrate SUB, and may be connected to power lines (e.g., pixel power lines, a common power line, etc.) connected to the pixels PX. In the following description of the embodiments, the term “connection” may encompass electrical and/or physical connection.

Although the number of first side lines SIL1 may be substantially equal to the number of second side lines SIL2 according to the one or more embodiments corresponding to FIGS. 1 and 2, the embodiments are not limited thereto. For example, the number of second side lines SIL2 may be less than the number of first side lines SIL1. Alternatively, some of the second side lines SIL2, for example, a plurality of second side lines SIL2 to which the same supply voltage is applied, may be formed integrally, and thus individual lines with a larger width may be formed.

The back face lines BFL (e.g., back face fan-out lines) may be located on the second surface BS of the substrate SUB, and may be connected to the side lines SIL. For example, the back face lines BFL may include first back face lines BFL1 connected to the respective first side lines SIL1, and second back face lines BFL2 connected to the respective second side lines SIL2. The first back face lines BFL1 may connect the first side lines SIL1 with the first circuit boards 200, and the second back face lines BFL2 may connect the second side lines SIL2 with the second circuit board 400.

Each of the device identifiers DID may be an identifier, such as an identification number assigned to every display device to distinguish display devices from one another. The device identifiers DID may be located on the second surface BS of the substrate SUB. The device identifiers DID may be spaced apart from the side lines SIL, the back face lines BFL, the first circuit boards 200, and the second circuit boards 400. As an example, the device identifiers DID may be electrically floating.

According to one or more embodiments of the present disclosure, the device identifiers DID may be a back metal layer formed of the same material as, and via the same process with, the back face lines BFL. According to one or more embodiments of the present disclosure, the back metal layer may be made up of a single layer or multiple layers of one of molybdenum (Mo), aluminum (AI), chromium (Cr), gold (Au), titanium (Ti), nickel (Ni), neodymium (Nd), and/or copper (Cu), or an alloy thereof.

The first circuit boards 200 may be located on the second surface BS of the substrate SUB. Each of the first circuit boards 200 may be connected to the respective one of the first back face lines BFL1 using a conductive adhesive member, such as an anisotropic conductive film. The first circuit boards 200 may be electrically connected to the first side lines SIL1 through the first back face lines BFL1. The first circuit boards 200 may be flexible printed circuit boards, printed circuit boards, or flexible films.

The source driver circuits 300 may generate data voltages, and may apply the data voltages to the data lines through the first circuit boards 200, the first back face lines BFL1, and the first side lines SIL1. Each of the source driver circuits 300 may be implemented as an integrated circuit (IC), and may be attached to the respective first circuit board 200. Alternatively, the source driver circuits 300 may be attached directly to the second surface BS of the substrate SUB using the chip on glass (COG) technique. In this instance, the display device 10 may not include the first circuit boards 200, and the source driver circuits 300 may apply data voltages to the data lines through the first back face lines BFL1 and the first side lines SIL1.

The second circuit board 400 may be located on the second surface BS of the substrate SUB. The second circuit board 400 may be connected to the second back face lines BFL2 using a conductive adhesive member. The second circuit board 400 may be electrically connected to the second side lines SIL1 through the second back face lines BFL2. The second circuit board 400 may be a flexible printed circuit board, a printed circuit board, or a flexible film.

The power supply circuit 500 may generate supply voltages required for driving the display panel 100, and may apply the supply voltages to the power lines through the second circuit board 400, the second back face lines BFL2, and the second side lines SIL2. For example, the power supply circuit 500 may generate a first supply voltage to apply it to the pixel power lines through the second circuit board 400, the plurality of second back face lines BFL2, and the plurality of second side lines SIL2. In addition, the power supply circuit 500 may generate a second supply voltage to apply the second supply voltage to the common power line through the second circuit board 400, through the plurality of second back face lines BFL2, and through the plurality of second side lines SIL2. The power supply circuit 500 may be implemented as an integrated circuit (IC), and may be attached to the second circuit board 400. Alternatively, the power supply circuit 500 may be attached directly on the second surface BS of the substrate SUB using the chip-on-glass (COG) technique. In this instance, the display device 10 may not include the second circuit board 400, and the power supply circuit 500 may apply the first supply voltage and the second supply voltage to the pixel power lines and the common power line, respectively, through the second back face lines BFL2 and the second side lines SIL2.

As shown in FIGS. 1 and 2, using the side lines SIL, the pixels PX, the signal lines and the power lines located on the first surface FS of the substrate SUB may be connected to the back face lines BFL, the first circuit boards 200, the source driver circuits 300, the second circuit board 400, and/or the power supply circuit 500, etc. located on the second side BS of the substrate SUB. In this manner, it is possible to remove or eliminate a flexible film bent along the side surfaces SS of the substrate SUB, so that a bezel-less display device can be implemented.

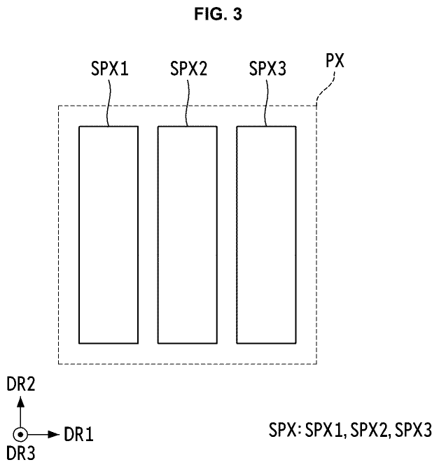

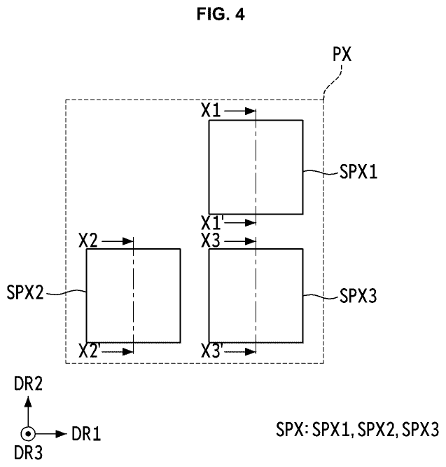

FIG. 3 is a plan view showing a pixel according to one or more embodiments of the present disclosure. FIG. 4 is a plan view showing a pixel according to one or more embodiments of the present disclosure.

FIGS. 3 and 4 show different embodiments in terms of the arrangement structure of sub-pixels SPX included in a pixel PX. In addition, FIGS. 3 and 4 schematically show the pixels PX according to the respective embodiments, based on emission areas (e.g., areas where light-emitting element chips are attached) of sub-pixels SPX.

Referring to FIGS. 3 and 4, the pixels PX may include a plurality of sub-pixels SPX. Although each of the pixels PX includes three sub-pixels SPX, including a first sub-pixel SPX1, a second sub-pixel SPX2 and a third sub-pixel SPX3 according to the embodiments of FIGS. 3 and 4, the number, ratio and/or type of sub-pixels SPX forming each of the pixels PX may vary depending on embodiments.

The sub-pixels SPX may be connected to signal lines and power lines. For example, each of the sub-pixels SPX may be connected to at least one gate line from which at least one gate signal including a scan signal is applied, a data line from which data voltage is applied, a pixel power line from which a first supply voltage (e.g., a high-level pixel voltage) is applied, a common power line from which a second supply voltage (e.g., a low-level pixel voltage or common voltage) is applied, etc. The type or number of the signal lines and the power lines connected to the sub-pixels SPX may vary depending on the structure or operation scheme of the sub-pixels SPX.

The sub-pixels SPX may have a rectangular or other shape when viewed from the top. For example, each of the first sub-pixel SPX1, the second sub-pixel SPX2, and the third sub-pixel SPX3 may have a rectangular or square shape when viewed from the top as shown in FIGS. 3 and 4, or may have a diamond shape or other shapes when viewed from the top.

The sub-pixels SPX of each of the pixels PX may be arranged sequentially or continuously along the first direction DR1, or may be arranged in a corresponding shape along the first direction DR1 and the second direction DR2. For example, a first sub-pixel SPX1, a second sub-pixel SPX2, and a third sub-pixel SPX3 of the pixel PX may be arranged in the first direction DR1 as shown in FIG. 3. Alternatively, as shown in FIG. 4, a first sub-pixel SPX1 and a second sub-pixel SPX2 are arranged diagonally in the pixel PX, and a third sub-pixel SPX3 may be adjacent to the second sub-pixel SPX2 in the first direction DR1, and may be adjacent to the first sub-pixel SPX1 in the second direction DR2. The sub-pixels SPX may be arranged in other arrangements in each pixel area.

The sub-pixels SPX (or the emission areas of the sub-pixels SPX) may have substantially the same size or different sizes. For example, the first sub-pixel SPX1, the second sub-pixel SPX2, and the third sub-pixel SPX3 may have substantially the same or similar sizes as shown in FIGS. 3 and 4. Alternatively, depending on the luminous efficiency or white balance of the sub-pixels SPX, at least two of the first sub-pixels SPX1, the second sub-pixels SPX2, and/or the third sub-pixels SPX3 may have different sizes.

According to one or more embodiments of the present disclosure, the sub-pixels SPX may emit light of different respective colors. For example, the first sub-pixel SPX1 may emit light of a first color (e.g., red light in a wavelength range of about 600 nm to about 750 nm), the second sub-pixel SPX2 may emit light of a second color (e.g., green light in a wavelength range of about 480 nm to about 560 nm), and the third sub-pixel SPX3 may emit light of a third color (e.g., blue light in a wavelength range of about 370 nm to about 460 nm). It should be understood, however, that the embodiments of the present disclosure are not limited thereto. For example, each pixel PX may include at least two sub-pixels SPX that emit light of the same color.

Each of the sub-pixels SPX may include a light-emitting unit including at least one light-emitting element. Each of the sub-pixels SPX may further include a pixel circuit including circuit elements (e.g., a plurality of thin-film transistors and at least one capacitor) for driving or controlling the light-emitting unit. The pixel circuit of each sub-pixel SPX may be electrically connected to the light-emitting element included in the light-emitting unit of that sub-pixel SPX. The light-emitting unit and the pixel circuit of each of the sub-pixels SPX may or may not overlap each other.

According to one or more embodiments of the present disclosure, each of the sub-pixels SPX may include an inorganic light-emitting element. For example, each of the first sub-pixel SPX1, the second sub-pixel SPX2, and the third sub-pixel SPX3 may include at least one inorganic light-emitting element including an inorganic semiconductor. The inorganic light-emitting element may be, but is not limited to, a micro light-emitting diode (hereinafter referred to as a micro LED) having the length in the first direction DR1, the length in the second direction DR2, and the length in the third direction DR3 (e.g., thickness or height) of several to hundreds micrometers (μm). For example, the type, material, structure and/or size of the light-emitting element forming the light-emitting unit of each of the sub-pixels SPX may vary depending on embodiments.

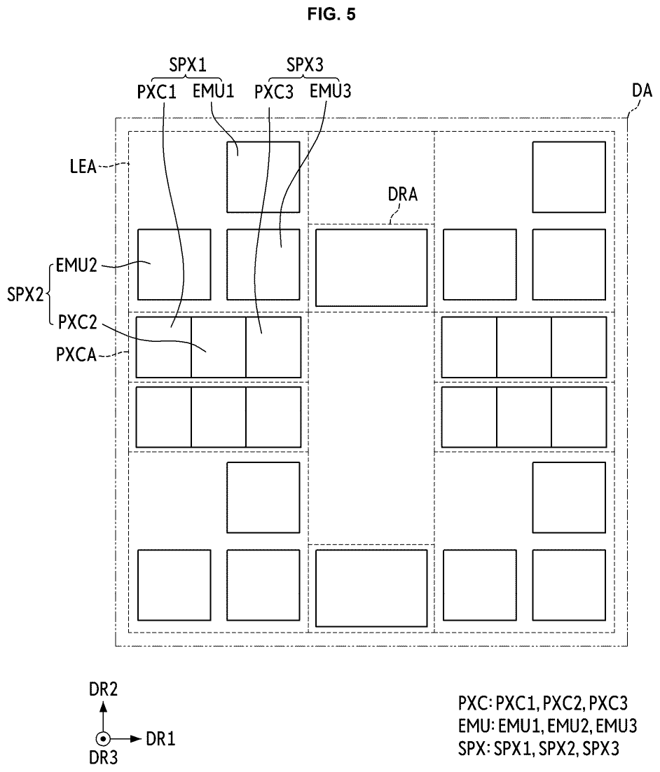

FIG. 5 is a plan view showing a display area according to one or more embodiments of the present disclosure. For example, FIG. 5 shows a part of the display area DA including pixel areas in which four pixels PX are arranged adjacent to each other in the first direction DR1 and the second direction DR2. Although the display area DA further includes a driver circuit area DRA located between pixel areas in the example of FIG. 5, the embodiments are not limited thereto. For example, the display area DA may include no driver circuit area DRA, or may include a driver circuit area DRA that overlaps the pixel areas (e.g., a part of light-emitting element areas LEA).

Referring to FIG. 5, each of the sub-pixels SPX may include a light-emitting unit EMU and a pixel circuit PXC. For example, the first sub-pixel SPX1 may include a first light-emitting unit EMU1 and a first pixel circuit PXC1, the second sub-pixel SPX2 may include a second light-emitting unit EMU2 and a second pixel circuit PXC2, and the third sub-pixel SPX3 may include a third light-emitting unit EMU3 and a third pixel circuit PXC3. The light-emitting unit EMU and the pixel circuit PXC of each of the sub-pixels SPX may be electrically connected with each other.

The light-emitting unit EMU of each of the sub-pixels SPX may include at least one light-emitting element. According to one or more embodiments of the present disclosure, the first light-emitting unit EMU1 may include a first color light-emitting element (e.g., a red micro LED) that emits light of the first color. According to one or more other embodiments, the first light-emitting unit EMU1 may include a third color light-emitting element (e.g., a blue micro LED) that emits light of the third color, and the first sub-pixel SPX1 may further include a light conversion layer and/or a color filter layer located on the third color light-emitting element to convert the third color light into the first color light.

The second light-emitting unit EMU2 may include a second color light-emitting element (e.g., a green micro LED) that emits light of the second color. According to one or more other embodiments, the second light-emitting unit EMU2 may include a third color light-emitting element that emits light of the third color, and the second sub-pixel SPX2 may further include a light conversion layer and/or a color filter layer located on the third color light-emitting element to convert the third color light into the second color light.

The third light-emitting unit EMU3 may include a third color light-emitting element (e.g., a blue micro LED) that emits light of the third color. According to one or more embodiments of the present disclosure, the third sub-pixel SPX3 may further include a light-transmitting layer (or light-scattering layer) and/or a color filter layer located on the third color light-emitting element, or may include no light-transmitting layer or no color filter layer.

The light-emitting units EMU and the pixel circuits PXC of the sub-pixels SPX forming each pixel PX may or may not overlap one another. For example, as shown in FIG. 5, a light-emitting element area LEA where the first light-emitting unit EMU1, the second light-emitting unit EMU2, and the third light-emitting unit EMU3 are located may not substantially overlap a pixel circuit area PXCA where the first pixel circuit PXC1, the second pixel circuit PXC2, and the third pixel circuit PXC3 are located. For example, the light-emitting element area LEA and the pixel circuit area PXCA of each pixel PX may be adjacent to each other in the second direction DR2. Alternatively, the light-emitting units EMU and the pixel circuits PXC of the sub-pixels SPX may at least partially overlap each other. For example, as the light-emitting element area LEA and the pixel circuit area PXCA of each pixel PX overlap each other, the ratio of the area occupied by the emission areas where light exits can be increased relative to the total area of the display area DA.

The display area DA may further include driver circuit areas DRA each located around the respective pixel area including the light-emitting element area LEA and the pixel circuit area PXCA (or the respective pixel circuit area PXCA). The driver circuit areas DRA may be located between pixel areas (or between pixel circuit areas PXCA). Although FIG. 5 discloses the driver circuit areas DRA do not substantially overlap the light-emitting element areas LEA or the pixel circuit areas PXCA, the embodiments are not limited thereto. For example, the driver circuit areas DRA may partially or entirely overlap with at least one light-emitting element area LEA.

Circuit elements forming at least one driver circuit for driving the pixels PX may be located in the driver circuit areas DRA. For example, in the driver circuit areas DRA, circuit elements that form a scan driver circuit, etc. (e.g., thin-film transistors and capacitors that form stage circuits of the scan driver circuit) may be located. By placing the scan driver circuit inside the display area DA, the non-display area of the display panel 100 (e.g., the bezel area surrounding the display area DA) can be reduced, or the non-display area can be substantially eliminated.

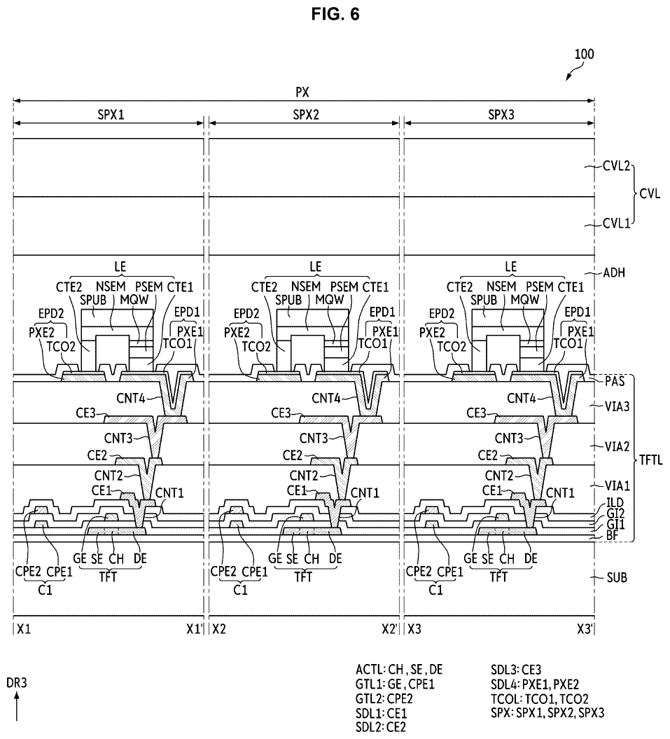

FIG. 6 is a cross-sectional view showing a display panel according to one or more embodiments of the present disclosure. For example, FIG. 6 shows a cross-section of a part of the display panel 100 taken along the lines X1-X1′, X1-X2′ and X3-X3′ of FIG. 4.

In the example shown in FIG. 6, elements that may be included in each sub-pixel SPX includes a thin-film transistor TFT located in the thin-film transistor layer TFTL on the substrate SUB, and included in each pixel circuit PXC (e.g., a thin-film transistor TFT connected to a light-emitting element LE of the respective sub-pixel SPX by connection electrodes CE1, CE2, and CE3); a capacitor C1; and the light-emitting element LE located on the thin-film transistor layer TFT, and included in each light-emitting unit EMU. In addition, although each of the sub-pixels SPX includes a flip-chip type micro LED including a first contact electrode CTE1 and a second contact electrode CTE2 as the light-emitting element LE in the example shown in FIG. 6, the type or structure of the light-emitting elements LE that may be located in the sub-pixels SPX are not limited thereto.

Referring to FIG. 6, the display panel 100 may include a substrate SUB, a thin-film transistor layer TFTL located on the substrate SUB, and light-emitting elements LE located on the thin-film transistor layer TFTL (or a light-emitting element layer including the light-emitting elements LE). The display panel 100 may further include an adhesive layer ADH (or filler), and a cover layer CVL (or protective layer) located over the thin-film transistor layer TFTL and the light-emitting elements LE.

The substrate SUB may be a base substrate or a base member for forming the display panel 100. According to one or more embodiments of the present disclosure, the substrate SUB may be a flexible substrate that can be bent, folded, or rolled. For example, the substrate SUB may include an insulating material, such as a polymer resin including polyimide (PI). Alternatively, the substrate SUB may be a rigid substrate, such as a glass substrate.

The thin-film transistor layer TFTL may include a plurality of insulating layers, a plurality of conductive layers, and at least one semiconductor layer (or active layers ACTL included in the semiconductor layer) located on the substrate SUB. For example, the thin-film transistor layer TFTL may include a buffer layer BF, an active layer ACTL, a first gate insulator GI1, a first gate conductive layer GTL1, a second gate insulator GI2, a second gate conductive layer GTL2, an interlayer dielectric layer ILD, a first source conductive layer SDL1, a first planarization layer VIA1, a second source conductive layer SDL2 (or first conductive layer), a second planarization layer VIA2, a third source conductive layer SDL3, a third planarization layer VIA3, a fourth source conductive layer SDL4, a transparent conductive layer TCOL (or second conductive layer), and a passivation layer PAS sequentially arranged on the substrate SUB.

According to one or more embodiments of the present disclosure, the thin-film transistor layer TFTL may further include at least one insulating layer or conductive layer. For example, the thin-film transistor layer TFTL may further include at least one of an inorganic insulating layer covering the first planarization layer VIA1, an inorganic insulating layer covering the second planarization layer VIA2, and/or an inorganic insulating layer covering the third planarization layer VIA3.

The buffer layer BF may be located on the substrate SUB. The buffer layer BF may include an inorganic material that can reduce or prevent permeation of air or moisture. The buffer layer BF may include a plurality of inorganic films sequentially stacked on the substrate SUB. For example, the buffer layer BF may be formed as a stack of multiple films including at least two of a silicon nitride layer, a silicon oxynitride layer, a silicon oxide layer, a titanium oxide layer, and/or an aluminum oxide layer.

The active layer ACTL may be located on the buffer layer BF. The active layer ACTL may include a channel CH, a source electrode SE (or source region), and a drain electrode DE (or drain region) of each of the thin-film transistors TFT. The channel CH may overlap with a gate electrode GE of the thin-film transistor TFT. The source electrode SE and the drain electrode DE may be connected with each other through the channel CH, and may be conductive regions that have a higher conductivity than the channel CH. For example, portions of the active layer ACTL located on the both sides of the channel CH may be made conductive by heat treatment, doping, or other methods (etching of the first gate insulator GI1, etc.) to form the source electrode SE and the drain electrode DE.

The active layer ACTL may include polycrystalline silicon, single crystal silicon, low-temperature polycrystalline silicon, amorphous silicon, or an oxide semiconductor. The active layers ACTL of the thin-film transistors TFT included in the sub-pixels SPX, etc. may be located in the same layer in the thin-film transistor layer TFTL. It should be understood, however, that the embodiments of the present disclosure are not limited thereto. For example, according to one or more other embodiments, the thin-film transistor layer TFTL may include a first active layer including a first semiconductor material (e.g., polycrystalline silicon, single crystalline silicon, low-temperature polycrystalline silicon, or amorphous silicon), and a second active layer located in a different layer from the first active layer, and including a second semiconductor material (e.g., an oxide semiconductor).

The first gate insulator GI1 may be located on the active layer ACTL. The first gate insulator GI1 may insulate the gate electrode GE from the channel CH of the thin-film transistor TFT. The first gate insulator GI1 may include an inorganic film. For example, the first gate insulator GI1 may include at least one of a silicon nitride layer, a silicon oxynitride layer, a silicon oxide layer, a titanium oxide layer, and/or an aluminum oxide layer.

The first gate conductive layer GTL1 may be located on the first gate insulator GI1. The first gate conductive layer GTL1 may include the gate electrode GE of the thin-film transistor TFT and a first capacitor electrode CPE1 of the capacitor C1. According to one or more embodiments of the present disclosure, the first gate conductive layer GTL1 may be a single layer or multiple layers of one of molybdenum (Mo), aluminum (Al), chromium (Cr), gold (Au), titanium (Ti), nickel (Ni), neodymium (Nd), and/or copper (Cu), or an alloy thereof.

The second gate insulator GI2 may be located on the first gate conductive layer GTL1. The second gate insulator GI2 may insulate the first gate conductive layer GTL1 from the second gate conductive layer GTL2. The second gate insulator GI2 may include an inorganic film. For example, the second gate insulator GI2 may include at least one of a silicon nitride layer, a silicon oxynitride layer, a silicon oxide layer, a titanium oxide layer, and/or an aluminum oxide layer.

The second gate conductive layer GTL2 may be located on the second gate insulator GI2. The second gate conductive layer GTL2 may include a second capacitor electrode CPE2 of the capacitor C1. According to one or more embodiments of the present disclosure, the second gate conductive layer GTL2 may be a single layer or multiple layers of one of molybdenum (Mo), aluminum (Al), chromium (Cr), gold (Au), titanium (Ti), nickel (Ni), neodymium (Nd), and/or copper (Cu), or an alloy thereof.

The interlayer dielectric layer ILD may be located on the second gate conductive layer GTL2. The interlayer dielectric layer ILD may insulate the first source conductive layer SDL1 from the second gate conductive layer GTL2. The interlayer dielectric layer ILD may include an inorganic film. For example, the interlayer dielectric layer ILD may include one of a silicon nitride layer, a silicon oxynitride layer, a silicon oxide layer, a titanium oxide layer, and/or an aluminum oxide layer.

The first source conductive layer SDL1 may be located on the interlayer dielectric layer ILD. The first source conductive layer SDL1 may include a first connection electrode CE1 (or the source electrode or the drain electrode of thin-film transistor TFT).

The first connection electrode CE1 may be connected to one electrode (e.g., the drain electrode DE) of the thin-film transistor TFT through a first contact hole CNT1 penetrating the interlayer dielectric layer ILD, the second gate insulator GI2 and the first gate insulator GI1. The first connection electrode CE1 may be connected to a second connection electrode CE2 through a second contact hole CNT2 penetrating the first planarization layer VIA1. For example, the first connection electrode CE1 may electrically connect the drain electrode DE of the thin-film transistor TFT with the second connection electrode CE2. The first source conductive layer SDL1 may be made up of a single layer or multiple layers of one of molybdenum (Mo), aluminum (Al), chromium (Cr), gold (Au), titanium (Ti), nickel (Ni), neodymium (Nd), and/or copper (Cu), or an alloy thereof.

The first planarization layer VIA1 may be located on the interlayer dielectric layer ILD and the first source conductive layer SDL1. The first planarization layer VIA1 may provide a flat surface over the first source conductive layer SDL1. The first planarization layer VIA1 may include an organic film, such as an acryl resin, an epoxy resin, a phenolic resin, a polyamide resin, and/or a polyimide resin.

The second source conductive layer SDL2 may be located on the first planarization layer VIA1. The second source conductive layer SDL2 may include the second connection electrode CE2.

The second connection electrode CE2 may be connected to a third connection electrode CE3 through a third contact hole CNT3 penetrating the second planarization layer VIA2. In addition, the second connection electrode CE2 may penetrate the first planarization layer VIA1 to be connected to the first connection electrode CE1. For example, the second connection electrode CE2 may electrically connect the third connection electrode CE3 with the first connection electrode CE1.

According to one or more embodiments of the present disclosure, the second source conductive layer SDL2 may be made up of a single layer or multiple layers of one of molybdenum (Mo), aluminum (Al), chromium (Cr), gold (Au), titanium (Ti), nickel (Ni), neodymium (Nd), and/or copper (Cu), or an alloy thereof.

The second planarization layer VIA2 may be located on the second source conductive layer SDL2. The second planarization layer VIA2 may provide a flat surface over the second source conductive layer SDL2. The second planarization layer VIA2 may include an organic film, such as an acryl resin, an epoxy resin, a phenolic resin, a polyamide resin, and/or a polyimide resin.

The third source conductive layer SDL3 may be located on the second planarization layer VIA2. The third source conductive layer SDL3 may include the third connection electrode CE3.

The third connection electrode CE3 may be connected to a first pixel electrode PXE1 through a fourth contact hole CNT4 penetrating the third planarization layer VIA3. In addition, the third connection electrode CE3 may penetrate the second planarization layer VIA2 to be connected to the second connection electrode CE2. For example, the third connection electrode CE3 may electrically connect the first pixel electrode PXE1 with the second connection electrode CE2. According to one or more embodiments of the present disclosure, the third source conductive layer SDL3 may be made up of a single layer or multiple layers of one of molybdenum (Mo), aluminum (Al), chromium (Cr), gold (Au), titanium (Ti), nickel (Ni), neodymium (Nd), and/or copper (Cu), or an alloy thereof.

Although the thin-film transistor TFT is connected to the first electrode pad EPD1 (e.g., the first pixel electrode PXE1 of first electrode pad EPD1) by the plurality of connection electrodes (e.g., the first connection electrode CE1, the second connection electrode CE2, and the third connection electrode CE3) located in the source conductive layers (e.g., the first source conductive layer SDL1, the second source conductive layer SDL2, and the third source conductive layer SDL3) on the thin-film transistor TFT in the example shown in FIG. 6, the embodiments of the present disclosure are not limited thereto. For example, the thin-film transistor TFT may be connected to the first electrode pad EPD1 by a single connection electrode (e.g., the first connection electrode CE1, the second connection electrode CE2, or the third connection electrode CE3), or may be directly connected to the first electrode pad EPD1 without any connection electrode. In addition, the numbers of the source conductive layers SDL1, SDL2, SDL3, and SDL4 and/or the connection electrodes CE1, CE2, and CE3 included in the thin-film transistor layer TFTL may vary depending on embodiments.

The third planarization layer VIA3 may be located on the third source conductive layer SDL3. The third planarization layer VIA3 may provide a flat surface over the third source conductive layer SDL3. The third planarization layer VIA3 may include an organic film, such as an acryl resin, an epoxy resin, a phenolic resin, a polyamide resin, and/or a polyimide resin.

The fourth source conductive layer SDL4 may be located on the third planarization layer VIA3. The fourth source conductive layer SDL4 may include the first pixel electrode PXE1 and a second pixel electrode PXE2. The first pixel electrode PXE1 and the second pixel electrode PXE2 may be spaced apart from each other in the emission area of each sub-pixel SPX. The fourth source conductive layer SDL4 may be made up of a single layer or multiple layers of one of molybdenum (Mo), aluminum (Al), chromium (Cr), gold (Au), titanium (Ti), nickel (Ni), neodymium (Nd), and/or copper (Cu), or an alloy thereof.

The first pixel electrode PXE1 may penetrate the third planarization layer VIA3 to be connected to the third connection electrode CE3. The first pixel electrode PXE1, alone or together with a first transparent electrode TCO1, may form the first electrode pad EPD1 (e.g., an anode electrode pad) of the sub-pixel SPX.

The second pixel electrode PXE2, alone or together with a second transparent electrode TCO2, may form the second electrode pad EPD2 (e.g., a cathode electrode pad) of the sub-pixel SPX. The second electrode pad EPD2 may be connected to the common power line from which the second supply voltage is applied.

The transparent conductive layer TCOL (or metal oxide conductive layer) may be located on the fourth source conductive layer SDL4. For example, the transparent conductive layer TCOL may be located at the top of the conductive layers located on the substrate SUB (e.g., the gate conductive layers GTL1 and GTL2, the source conductive layers SDL1, SDL2, SDL3, and/or SDL4). The transparent conductive layer TCOL may be included in the thin-film transistor layer TFTL.

The transparent conductive layer TCOL may include a first transparent electrode TCO1 and a second transparent electrode TCO2. The transparent conductive layer TCOL may include a transparent conductive material. For example, the transparent conductive layer TCOL may include a transparent conductive oxide (TCO), such as indium tin oxide (ITO), indium zinc oxide (IZO), and/or indium tin zinc oxide (ITZO). By placing the first transparent electrode TCO1 and the second transparent electrode TCO2 on the first pixel electrode PXE1 and the second pixel electrode PXE2, respectively, adhesion between the first and second electrode pads EPD1 and EPD2 and the first and second contact electrodes CTE1 and CTE2 of the light-emitting elements LE can be increased.

The first transparent electrode TCO1 may be located on the first pixel electrode PXE1. The first transparent electrode TCO1 may form a multi-layer first electrode pad EPD1 together with the first pixel electrode PXE1.

The first electrode pad EPD1 may be located on the connection electrodes CE1, CE2, and CE3. The first electrode pad EPD1 may be connected between one of the connection electrodes CE1, CE2, and/or CE3 and a first contact electrode CTE1 of the light-emitting element LE. In addition, the first electrode pad EPD1 may be connected to the thin-film transistor TFT through the connection electrodes CE1, CE2, and CE3. The first electrode pad EPD1 may receive driving current from the pixel circuit PXC through the thin-film transistor TFT. The light-emitting element LE may emit light with a luminance in proportion to the driving current supplied to the first electrode pad EPD1.

The second transparent electrode TCO2 may be located on the second pixel electrode PXE2. The second transparent electrode TCO2 may form a multi-layer second electrode pad EPD2 together with the second pixel electrode PXE2.

The second electrode pad EPD2 may be located on one of the connection electrodes CE1, CE2, and/or CE3. The second electrode pad EPD2 may be connected to the second contact electrode CTE2 of the light-emitting element LE. In addition, the second electrode pad EPD2 may be connected to the common power line. For example, the second electrode pad EPD2 may be connected between the second contact electrode CTE2 of the light-emitting element LE and the common power line.

The passivation layer PAS may be located on the third planarization layer VIA3, the fourth source conductive layer SDL4, and the transparent conductive layer TCOL. For example, the passivation layer PAS may be located on the third planarization layer VIA3, and may cover the edges of the first electrode pad EPD1 and the second electrode pad EPD2, and may be open to expose other portions of the first and second electrode pads EPD1 and EPD2 (e.g., portions of the upper surfaces of the first and second electrode pads EPD1 and EPD2). According to one or more embodiments, the passivation layer PAS may include an inorganic film. For example, the passivation layer PAS may include one of a silicon nitride layer, a silicon oxynitride layer, a silicon oxide layer, a titanium oxide layer, and/or an aluminum oxide layer.

The light-emitting element LE may be connected between the first electrode pad EPD1 and the second electrode pad EPD2. The light-emitting element LE may be, but is not limited to, a flip-chip type micro LED located to face the first pixel electrode PXE1 and the second pixel electrode PXE2.

The light-emitting element LE may be an inorganic light-emitting element containing an inorganic material, such as GaN. For example, the light-emitting element LE may be, but is not limited to, a micro LED having the length in the first direction DR1, the length in the second direction DR2, and the length in the third direction DR3 of dozens of micrometers (e.g., about 100 μm or less).

The light-emitting element LE may be formed by being grown on a semiconductor substrate, such as a silicon wafer. For example, after a plurality of light-emitting elements LE is formed on a semiconductor substrate, they may be transferred or located on the first electrode pad EPD1 and the second electrode pad EPD2 of each of the sub-pixels SPX.

The light-emitting element LE may include an n-type semiconductor layer NSEM (or the first semiconductor layer of light-emitting element LE), an emissive layer MQW (e.g., the active layer of light-emitting element LE), a p-type semiconductor layer PSEM (or the second semiconductor layer of light-emitting element LE), a first contact electrode CTE1, and a second contact electrode CTE2. The light-emitting element LE may further include a base substrate SPUB. The base substrate SPUB may be, but is not limited to, a sapphire substrate.

The n-type semiconductor NSEM may be located on a surface (e.g., the lower surface) of the base substrate SPUB. The n-type semiconductor NSEM may include GaN doped with an n-type dopant, such as Si, Ge, and/or Sn. The material and/or dopant of the n-type semiconductor layer NSEM may vary depending on embodiments.

The emissive layer MQW may be located on a surface (e.g., lower surface) of the n-type semiconductor layer NSEM so that it overlaps with a part of the n-type semiconductor layer NSEM. The emissive layer MQW may include a material having a single or multiple quantum well structure. When the active layer MQW includes a material having the multiple quantum well structure, well layers and barrier layers may be alternately stacked on one another in the structure. The well layers may include InGaN, and the barrier layers may include GaN or AlGaN, but the present disclosure is not limited thereto. For example, the emissive layer MQW may have a structure in which a semiconductor material having a large band gap energy and a semiconductor material having a small band gap energy are alternately stacked on one another, and may include other Group III to Group V semiconductor materials depending on the wavelength range of the emitted light. The material or structure of the emissive layer MQW may vary depending on embodiments.

The p-type semiconductor layer PSEM may be located on a surface (e.g., lower surface) of the emissive layer MQW. The p-type semiconductor layer PSEM may include GaN doped with a p-type dopant, such as Mg, Zn, Ca, Se, and/or Ba. The material and/or dopant of the p-type semiconductor layer PSEM may vary depending on embodiments.

The first contact electrode CTE1 may be located on a surface (e.g., lower surface) of the p-type semiconductor layer PSEM. In addition, the first contact electrode CTE1 may be located on the first electrode pad EPD1. For example, the first contact electrode CTE1 may be located between the first electrode pad EPD1 and the p-type semiconductor layer PSEM, and may electrically connect the first electrode pad EPD1 with the p-type semiconductor layer PSEM. The first contact electrode CTE1 and the first electrode pad EPD1 may be bonded with each other by a conductive adhesive member, such as an anisotropic conductive film and an anisotropic conductive paste. Alternatively, the first contact electrode CTE1 and the first electrode pad EPD1 may be bonded with each other via a soldering process.

The second contact electrode CTE2 may be located on a surface (e.g., lower surface) of the n-type semiconductor layer NSEM, and may be spaced apart from the emissive layer MQW. In addition, the second contact electrode CTE2 may be located on the second electrode pad EPD2. For example, the second contact electrode CTE2 may be located between the second electrode pad EPD2 and the p-type semiconductor layer PSEM, and may electrically connect the second electrode pad EPD2 with the n-type semiconductor layer NSEM. The second contact electrode CTE2 and the second electrode pad EPD2 may be bonded to each other via a conductive adhesive member or a soldering process.

The adhesive layer ADH may be located over the light-emitting elements LE. The adhesive layer ADH may adhere the light-emitting element layer including the light-emitting elements LE to the cover layer CVL. The adhesive layer ADH may be a transparent adhesive member capable of transmitting light. For example, the adhesive layer ADH may be an optically clear adhesive film or an optically clear resin.

The cover layer CVL may be located on the adhesive layer ADH. The cover layer CVL may be attached to the thin-film transistor layer TFTL and the light-emitting element layer by the adhesive layer ADH.

The cover layer CVL may be made up of multiple layers including a first cover layer CVL1 and a second cover layer CVL2. The first cover layer CVL1 may be a layer for adjusting light transmittance including a phase retardation layer, etc. that is designed to reduce the transmittance of external light (or reflected light). According to one or more embodiments of the present disclosure, the second cover layer CVL2 may be an anti-glare layer including a polarizer, etc.

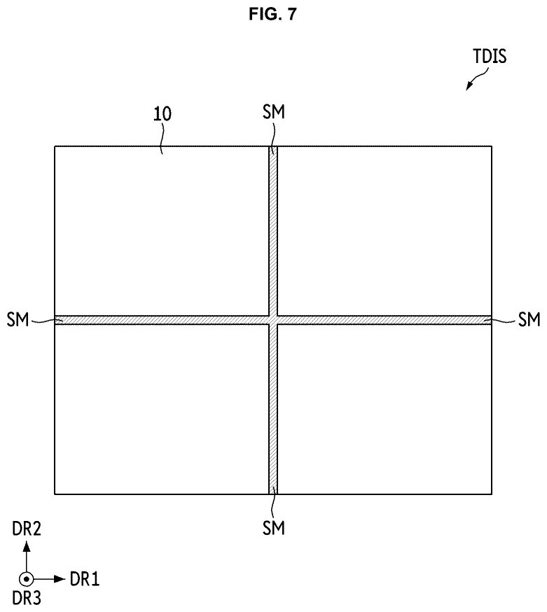

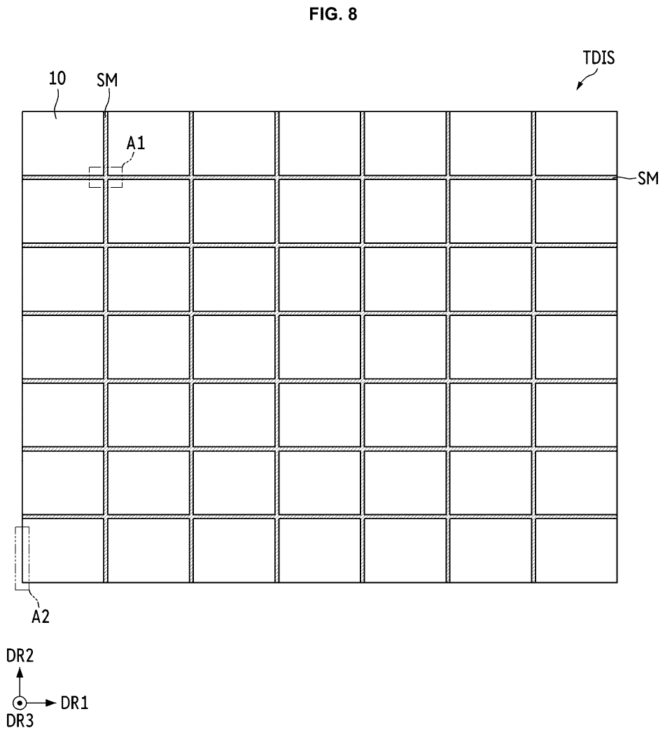

FIG. 7 is a plan view showing a tiled display according to one or more embodiments of the present disclosure. FIG. 8 is a plan view showing a tiled display according to one or more embodiments of the present disclosure. For example, FIGS. 7 and 8 show different embodiments in terms of the number and/or arrangement structure of display devices 10 forming tiled displays TDIS.

Referring to FIGS. 7 and 8, the tiled displays TDIS may include a plurality of display devices 10 and seams SM between the display devices 10. The display devices 10 may be arranged in the first direction DR1 and/or the second direction DR2.

According to the one or more embodiments corresponding to FIG. 7, the tiled display TDIS may include four display devices 10 arranged in a matrix of two rows and two columns in the first direction DR1 and the second direction DR2.

The number and arrangement structure of the display devices 10 forming the tiled display TDIS may vary depending on embodiments. For example, a larger tiled display TDIS can be implemented by using a greater number of display devices 10. For example, by arranging the display devices 10, each measuring 12.7 inches, in a matrix of seven rows and seven columns as shown in FIG. 8, a large, tiled display TDIS of about 89 inches can be implemented. A tiled displays TDIS of a variety of shapes and/or sizes can be implemented depending on the size, shape and/or arrangement structure of the display devices 10 forming the tiled display TDIS.

Each of the display devices 10 may be substantially identical to the display device 10 described above with reference to the embodiments of FIGS. 1 to 6. According to one or more embodiments of the present disclosure, the display devices 10 may have the same shape and size, but the present disclosure is not limited thereto.

According to one or more embodiments of the present disclosure, each of the display devices 10 may have, but is not limited to, a rectangular shape when viewed from the top. Some or all of the display devices 10 may be located at the edges of the tiled display TDIS, and may form the sides of the tiled display TDIS.

The seams SM may be located between the display devices 10. For example, the seams SM may be located between adjacent display devices 10 in the first direction DR1, and between adjacent display devices 10 in the second direction DR2.

The seams SM may include a coupling member or an adhesive member. In this instance, the display devices 10 may be connected with one another through a coupling member or adhesive member of the seams SM.

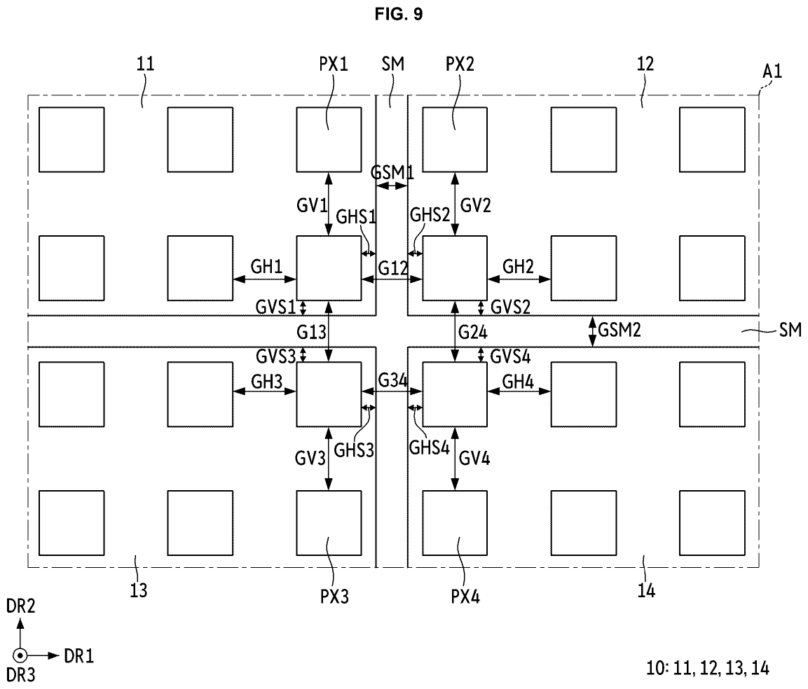

FIG. 9 is a plan view showing in detail seams of a tiled display according to one or more embodiments. For example, FIG. 9 is an enlarged view showing area A1 of FIG. 8.

Referring to FIG. 9, the seams SM may have the shape of a cross or a plus sign where a first display device 11, a second display device 12, a third display device 13, and a fourth display device 14 are adjacent to one another. The seams SM may be located between the first display device 11 and the second display device 12, between the first display device 11 and the third display device 13, between the second display device 12 and the fourth display device 14, and between the third display device 13 and the fourth display device 14.

The first display device 11 may include first pixels PX1 arranged in a matrix in the first direction DR1 and the second direction DR2. The second display device 12 may include second pixels PX2 arranged in a matrix in the first direction DR1 and the second direction DR2. The third display device 13 may include third pixels PX3 arranged in a matrix in the first direction DR1 and the second direction DR2. The fourth display device 14 may include fourth pixels PX4 arranged in a matrix in the first direction DR1 and the second direction DR2.

The minimum distance between neighboring first pixels PX1 in the first direction DR1 may be defined as a first horizontal separation distance GH1, and the minimum distance between neighboring second pixels PX2 in the first direction DR1 may be defined as a second horizontal separation distance GH2. The first horizontal separation distance GH1 may be substantially equal to the second horizontal separation distance GH2.

The seam SM may be located between the first pixel PX1 and the second pixel PX2 that are adjacent to each other in the first direction DR1. The minimum distance G12 between the neighboring first pixel PX1 and the second pixel PX2 in the first direction DR1 may be the sum of the minimum distance GHS1 between the first pixel PX1 and the seam SM in the first direction DR1, the minimum distance GHS2 between the second pixel PX2 and the seam SM in the first direction DR1, and the width GSM1 of the seam SM in the first direction DR1.

The minimum distance G12 between the first pixel PX1 and the second pixel PX2 neighboring in the first direction DR1, the first horizontal separation distance GH1, and the second horizontal separation distance GH2 may be substantially equal. For example, the minimum distance GHS1 between the first pixel PX1 and the seam SM may be less than the first horizontal separation distance GH1 in the first direction DR1, and the minimum distance GHS2 between the second pixel PX2 and the seam SM may be less than the second horizontal separation distance GH2 in the first direction DR1. In addition, the width GSM1 of the seam SM in the first direction DR1 may be less than the first horizontal separation distance GH1 or the second horizontal separation distance GH2.

The minimum distance between neighboring third pixels PX3 in the first direction DR1 may be defined as a third horizontal separation distance GH3, and the minimum distance between neighboring fourth pixels PX4 in the first direction DR1 may be defined as a fourth horizontal separation distance GH4. The third horizontal separation distance GH3 may be substantially equal to the fourth horizontal separation distance GH4.

The seam SM may be located between the third pixel PX3 and the fourth pixel PX4 that are adjacent to each other in the first direction DR1. The minimum distance G34 between the neighboring third pixel PX3 and the fourth pixel PX4 in the first direction DR1 may be the sum of the minimum distance GHS3 between the third pixel PX3 and the seam SM in the first direction DR1, the minimum distance GHS4 between the fourth pixel PX4 and the seam SM in the first direction DR1, and the width GSM1 of the seam SM in the first direction DR1.

The minimum distance G34 between the third pixel PX3 and the fourth pixel PX4 neighboring in the first direction DR1, the third horizontal separation distance GH3, and the fourth horizontal separation distance GH4 may be substantially equal. For example, the minimum distance GHS3 between the third pixel PX3 and the seam SM may be less than the third horizontal separation distance GH3 in the first direction DR1, and the minimum distance GHS4 between the fourth pixel PX4 and the seam SM may be less than the fourth horizontal separation distance GH4 in the first direction DR1. In addition, the width GSM1 of the seam SM in the first direction DR1 may be less than the third horizontal separation distance GH3 or the fourth horizontal separation distance GH4.

The minimum distance between neighboring first pixels PX1 in the second direction DR2 may be defined as a first vertical separation distance GV1, and the minimum distance between neighboring third pixels PX3 in the second direction DR2 may be defined as a third vertical separation distance GV3. The first vertical separation distance GV1 may be substantially equal to the third vertical separation distance GV4.

The seam SM may be located between the first pixel PX1 and the third pixel PX3 that are adjacent to each other in the second direction DR2. The minimum distance G13 between the neighboring first pixel PX1 and the third pixel PX3 in the second direction DR2 may be the sum of the minimum distance GVS1 between the first pixel PX1 and the seam SM in the second direction DR2, the minimum distance GVS3 between the third pixel PX3 and the seam SM in the second direction DR2, and the width GSM2 of the seam SM in the second direction DR2.

The minimum distance G13 between the first pixel PX1 and the third pixel PX3 neighboring in the second direction DR2, the first vertical separation distance GV1, and the third vertical separation distance GV3 may be substantially equal. For example, the minimum distance GVS1 between the first pixel PX1 and the seam SM may be less than the first vertical separation distance GV1 in the second direction DR2, and the minimum distance GVS3 between the third pixel PX3 and the seam SM may be less than the third vertical separation distance GV3 in the second direction DR2. In addition, the width GSM2 of the seam SM in the second direction DR2 may be less than the first vertical separation distance GV1 or the third vertical separation distance GV3.

The minimum distance between neighboring second pixels PX2 in the second direction DR2 may be defined as a second vertical separation distance GV2, and the minimum distance between neighboring fourth pixels PX4 in the second direction DR2 may be defined as a fourth vertical separation distance GV4. The second vertical separation distance GV2 may be substantially equal to the fourth vertical separation distance GV4.

The seam SM may be located between the second pixel PX2 and the fourth pixel PX4 that are adjacent to each other in the second direction DR2. The minimum distance G24 between the neighboring second pixel PX2 and the fourth pixel PX4 in the second direction DR2 may be the sum of the minimum distance GVS2 between the second pixel PX2 and the seam SM in the second direction DR2, the minimum distance GVS4 between the fourth pixel PX4 and the seam SM in the second direction DR2, and the width GSM2 of the seam SM in the second direction DR2.

The minimum distance G24 between the second pixel PX2 and the fourth pixel PX4 neighboring in the second direction DR2, the second vertical separation distance GV2, and the fourth vertical separation distance GV4 may be substantially equal. For example, the minimum distance GVS2 between the second pixel PX2 and the seam SM may be less than the second vertical separation distance GV2 in the second direction DR2, and the minimum distance GVS4 between the fourth pixel PX4 and the seam SM may be less than the fourth vertical separation distance GV4 in the second direction DR2. In addition, the width GSM2 of the seam SM in the second direction DR2 may be less than the second vertical separation distance GV2 or the fourth vertical separation distance GV4.

As shown in FIG. 9, to reduce or prevent visibility of the seams SM between images displayed by the display devices 10, the minimum distance between the pixels of neighboring display devices 10 may be substantially equal to the minimum distance between the pixels of each of the display devices 10.

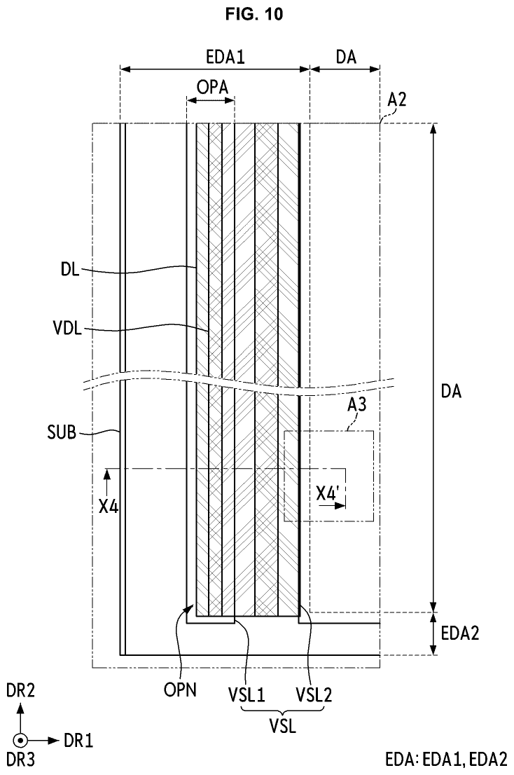

FIG. 10 is a plan view showing lines located at an edge of a display device according to one or more embodiments. For example, FIG. 10 shows an example of lines that may be located in area A2 of FIG. 8.

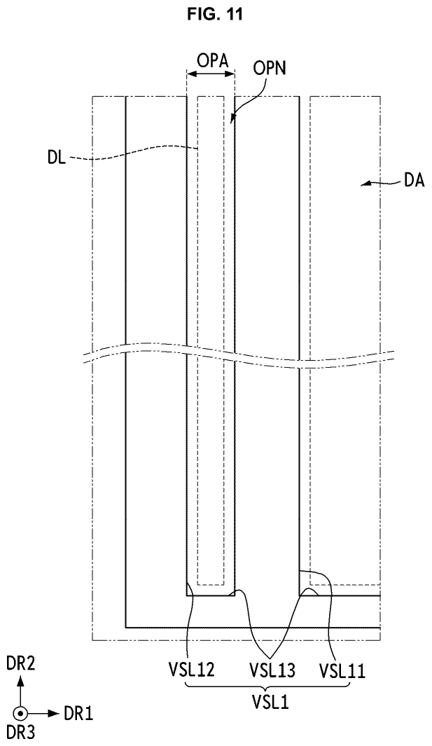

FIG. 11 is a plan view showing a first line layer of a common power line according to one or more embodiments. For example, FIG. 11 shows the first line layer VSL1 of the common power line VSL shown in FIG. 10.

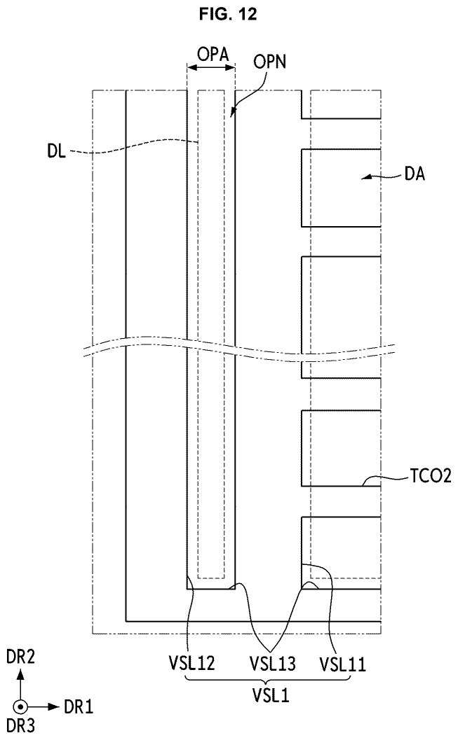

FIG. 12 is a plan view showing a first line layer of a common power line according to one or more embodiments. For example, FIG. 12 shows another example of the first line layer VSL1 of the common power line VSL shown in FIGS. 10 and 11.

Referring to FIGS. 10 to 12 in conjunction with FIG. 8, the display device 10 may include a display area DA where pixels PX are located, and an edge area EDA around the display area DA. For example, a substrate SUB and a display panel 100 including the same may include the display area DA as well as the edge area EDA surrounding the display area DA. The edge area EDA may include the border of the display device 10 (or the display panel 100) when viewed from the top. For example, the edge area EDA may include a first edge area EDA1 located on one side (e.g., the left side) of the display area DA, and a second edge area EDA2 that meets an end of the edge area EDA1, and is located on another side (e.g., lower side) of the display area.

The first edge area EDA1 and the second edge area EDA2 may extend in different directions. For example, the first edge area EDA1 may extend in the second direction DR2, and the second edge area EDA2 may extend in the first direction DR1 that crosses (for example, is perpendicular to) the second direction DR2.

Lines may be located in the edge area EDA of the display device 10. For example, in the first edge area EDA1 (e.g., the left edge of the display device 10), at least one data line DL, a pixel power line (also referred to as a first power line) (VDL), and a common power line VSL (also referred to as a second power line) may be located.

For example, the data lines DL connected to the first sub-pixels SPX1, the second sub-pixels SPX2, or the third sub-pixels SPX3 of the pixels PX arranged in the first pixel column among the pixels PX of the display area DA may be located in the first edge area EDA1 corresponding to the left edge of the display device 10, and may extend substantially in the second direction DR2. In addition, around the data line DL, a pixel power line VDL (e.g., a vertical line portion of the pixel power line VDL), and a common power line VSL (e.g., a vertical line portion of the common power line VSL) may be arranged.

According to one or more embodiments of the present disclosure, the lines located in the first edge area EDA1 of the display device 10 may be located in different conductive layers. In addition, at least two of the lines may overlap each other. In this manner, the width of the first edge area EDA1 of the display device 10 can be reduced or minimized, and a bezel-less (e.g., reduced bezel) display device can be implemented.

FIGS. 10 to 12 schematically show the shape and location of lines that may be located on the left side of the display area DA according to one or more embodiments. The lines may be in the form of vertical lines extended substantially in the second direction DR2 on the left side of the display area DA. It should be noted that the shape, width and/or location of the lines may vary in a variety of ways as needed. For example, a portion where a contact hole for connection to the pixels PX is formed may be expanded locally.

Although FIGS. 10 to 12 show an example of lines that may be located on the left side of the display area DA, at least one line may also pass on the right side of the display area DA. In addition, when a plurality of lines passes on the right side of the display area DA, the width of the edge portion EDA can be reduced and/or minimized as the lines located in different layers overlap one another.

The common power line VSL may be a multi-layer line including a first line layer VSL1 and a second line layer VSL2. The first line layer VSL1 of the common power line VSL may be an upper line layer of the common power line VSL, and may be located on the second line layer VSL2. The second line layer VSL2 of the common power line VSL may overlap a portion (e.g., the first portion VSL11) of the first line layer VSL1.

Each of the second line layer VSL2, the data line DL and the pixel power line VDL of the common power line VSL may be located in one of the source conductive layers SDL1, SDL2, SDL3, and/or SDL4 described above with reference to FIG. 6. The first line layer VSL1 of the common power line VSL may be located on the source conductive layers SDL1, SDL2, SDL3, and/or SDL4. For example, the first line layer VSL1 of the common power line VSL may be located in the transparent conductive layer TCOL described above with respect to FIG. 6. The conductive layer in which the first line layer VSL1 of the common power line VSL is located (e.g., the transparent conductive layer TCOL) may also be referred to as a second conductive layer.

The transparent conductive material included in the transparent conductive layer TCOL may be more resistant to corrosion than the conductive material included in each of the source conductive layers SDL1, SDL2, SDL3, and/or SDL4. In addition, the first line layer VSL1 of the common power line VSL including the transparent conductive material may have a larger width than each of the second line layer VSL2 of the common power line VSL, the data line DL, and the pixel power line VDL. The first line layer VSL1 may also extend further to the border of the display device 10. The first line layer VSL1 of the common power line VSL may extend even to another side of the display area DA (e.g., the second edge area EDA2 of the display device 10 located on the lower side of the display area DA). For example, a portion of the first line layer VSL1 of the common power line VSL may be located in the second edge area EDA2 corresponding to the lower edge of the display device 10. The second side lines SIL2 and/or front pads connected to the second side lines SIL2 may be located in the second edge area EDA2 of the display device 10.

The first line layer VSL1 of the common power line VSL may include an opening OPN in line with, overlapping, or exposing the data line DL or the pixel power line VDL, whichever is located more to the outside (e.g., the data line DL). For example, the first line layer VSL1 of the common power line VSL may be open in an open area OPA where the data line DL is located. Accordingly, the first line layer VSL1 of the common power line VSL may include/define an opening OPN in line with, overlapping, or exposing the data line DL. The open area OPA may include left and right margin areas in addition to the area where the data line DL is located. Accordingly, in the first edge area EDA1 of the display device 10, the first line layer VSL1 of the common power line VSL, and the data line DL may not substantially overlap each other.

The first line layer VSL1 of the common power line VSL may include a first portion VSL11 (also referred to as a first line portion) and a second portion VSL12 (also referred to as a second line portion) located in the first edge area EDA1 of the display device 10, and spaced apart from each other with the data line DL therebetween. For example, the first portion VSL11 and the second portion VSL12 of the first line layer VSL1 may be spaced apart from each other in the first direction DR1 with at least one opening OPN located in the open area OPA therebetween.

The first portion VSL11 of the first line layer VSL1 may be located between the display area DA and the data line DL. The first portion VSL11 of the first line layer VSL1 may extend substantially in the second direction DR2.

The second portion VSL12 of the first line layer VSL1 may be located between one end (e.g., the left end) of the display device 10 and the data line DL. For example, the second portion VSL12 of the first line layer VSL1 may be located between the end of the first edge area EDA1 and the data line DL, and may be located at the outermost position among the lines located on the first edge area EDA1 of the substrate SUB. The second portion VSL12 of the first line layer VSL1 may extend substantially in the second direction DR2.

The first line layer VSL1 of the common power line VSL may further include a third portion VSL13 (also referred to as a third line portion) located in the second edge area EDA2 of display device 10. The third portion VSL13 of the first line layer VSL1 may connect the first portion VSL11 of the first line layer VSL1 with the second portion VSL12 of the first line layer VSL1.

The third portion VSL13 of the first line layer VSL1 may extend substantially in the first direction DR1. The third portion VSL13 of the first line layer VSL1 may extend from the second edge area EDA2 of the display device 10 to the area where at least one second side line SIL2 is located, and may overlap with the at least one second side line SIL2. The third portion VSL13 of the first line layer VSL1 may be electrically connected to at least one second side line SIL2, and may be electrically connected to the power supply circuit 500 through the at least one second side line SIL2.

The first portion VSL11, the second portion VSL12, and the third portion VSL12 of the first line layer VSL1 may be formed integrally with each other. For example, the first portion VSL11, the second portion VSL12, and the third portion VSL12 of the first line layer VSL1 may refer to different parts of a single pattern.

The first line layer VSL1 of the common power line VSL may extend into the display area DA. For example, as shown in FIG. 12, the first portion VSL11 of the first line layer VSL1 may extend into the display area DA in the first direction DR1, and may be connected to the second transparent electrodes TCO2 of the sub-pixels SPX. For example, the first line layer VSL1 of the common power line VSL may be formed integrally with the second transparent electrodes TCO2 of the sub-pixels SPX.

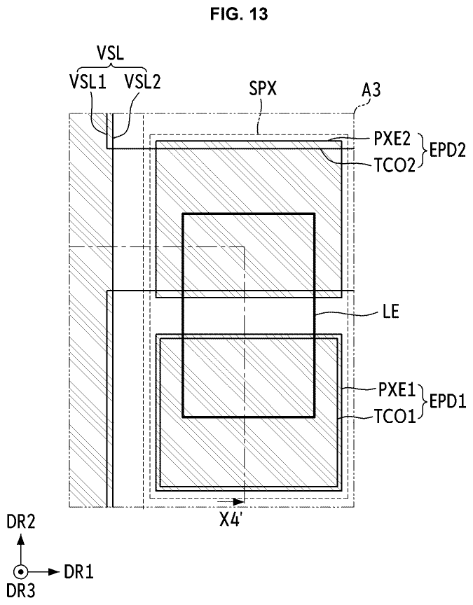

FIG. 13 is a plan view showing area A3 of FIG. 10 in detail. FIG. 13 shows area A3 of FIG. 10 according to one or more embodiments in which a first line layer VSL1 of a common power line VSL is formed integrally with a second transparent electrode TCO2 of a sub-pixel SPX.

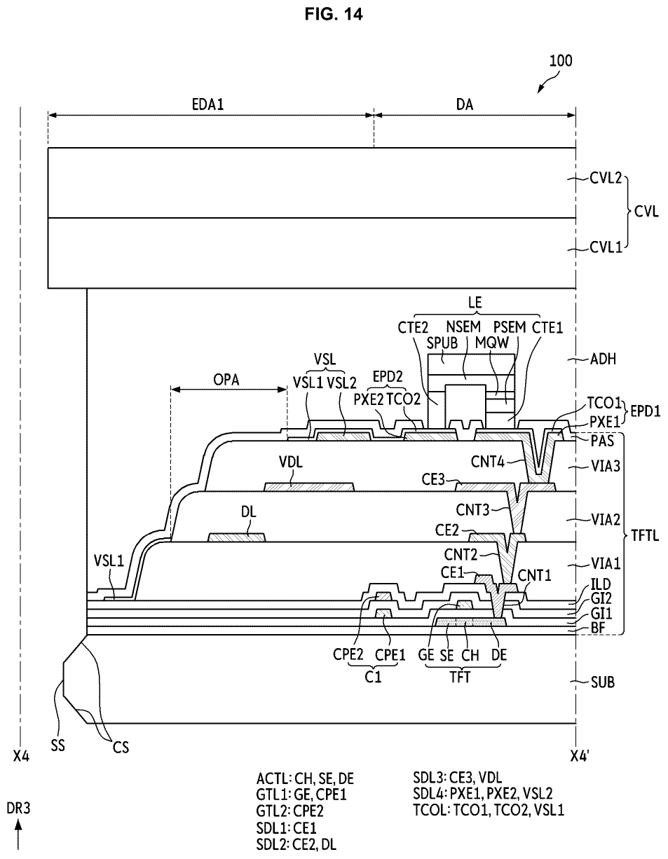

FIG. 14 is a cross-sectional view showing a display panel according to one or more embodiments of the present disclosure. For example, FIG. 14 shows a cross-section of a part of the display panel 100 taken along the line X4-X4′ of FIG. 10.

In the following description of the embodiments of FIGS. 13 and 14, the same reference numerals are assigned to elements similar or identical to those of the above-described embodiments, and redundant descriptions will be omitted. For example, the shape of the substrate SUB described above with reference to FIGS. 1 and 2, and the thin-film transistor layer TFTL, the light-emitting element LE, the adhesive layer ADH, and the cover layer CVL described above with reference to FIG. 6 will not be described again in detail.

Referring to FIGS. 13 and 14, a sub-pixel SPX may include at least one electrode pad, and a light-emitting element LE located on the electrode pad. For example, the sub-pixel SPX may include first and second electrode pads EPD1 and EPD2 spaced apart from each other, and a light-emitting element LE located on the first and second electrode pads EPD1 and EPD2.

According to one or more embodiments of the present disclosure, the first electrode pad EPD1 may include a first pixel electrode PXE1 located or included in the fourth source conductive layer SDL4, and a first transparent electrode TCO1 located or included in the transparent conductive layer TCOL. The second electrode pad EPD2 may include a second pixel electrode PXE2 located or included in the fourth source conductive layer SDL4, and a second transparent electrode TCO2 located or included in the transparent conductive layer TCOL.

The data line DL may be located or included in one source conductive layer (e.g., the second source conductive layer SDL2). For example, the data line DL may be located in the same layer as the second connection electrode CE2. The data line DL may be electrically connected to the pixel circuit PXC of the sub-pixel SPX, in one or more embodiments. The conductive layer in which the data line DL is located (e.g., the second source conductive layer SDL2) may also be referred to as a first conductive layer. The second source conductive layer SDL2 may be covered with at least one planarization layer (e.g., the second planarization layer VIA2).

The second planarization layer VIA2 may include an end (e.g., the left end) that covers the data line DL at the first edge area EDA1. According to one or more embodiments of the present disclosure, the end of the second planarization layer VIA2 and the data line DL may be located in the open area OPA where the first line layer VSL1 of the common power line VSL is opened. For example, the open area OPA of the first line layer VSL1 where at least one opening OPN is formed in the first line layer VSL1 may include an area where the outermost line in the first direction DR1 (e.g., the first data line DL) among the lines located in the first edge area EDA1 except the common power line VSL, and the end of the second planarization layer VIA2 covering the line are located.

The pixel power line VDL may be located or included in the third source conductive layer SDL3 on the second planarization layer VIA2. The pixel power line VDL may be electrically connected to the pixel circuit PXC of the sub-pixel SPX, in one or more embodiments. The third source conductive layer SDL3 may be covered with at least one planarization layer (e.g., a third planarization layer VIA3).

According to one or more embodiments of the present disclosure, the common power line VSL may include a second line layer VSL2 located or included in the fourth source conductive layer SDL4 on the third planarization layer VIA3, and a first line layer VSL1 located or included in the transparent conductive layer TCOL (or second conductive layer) on the second line layer VSL2. For example, the second line layer VSL2 of the common power line VSL, the first pixel electrode PXE1 of the first electrode pad EPD1 and the second pixel electrode PXE2 of the second electrode pad EPD2 may be located in the same layer, and may be spaced apart from each other. The first line layer VSL1 of the common power line VSL, the first transparent electrode TCO1 of the first electrode pad EPD1 and the second transparent electrode TCO2 of the second electrode pad EPD2 may be located in the same layer.

The common power line VSL may be electrically connected to the second electrode pad EPD2 of the sub-pixel SPX. For example, the first line layer VSL1 of the common power line VSL and the second transparent electrode TCO2 of the second electrode pad EPD2 may be formed integrally with each other.

The first line layer VSL1 of the common power line VSL may include/define an opening OPN in line with, overlapping, or exposing the data line DL in the first edge area EDA1 of the display device 10. For example, the first line layer VSL1 of the common power line VSL may be open in an open area OPA of the first edge area EDA1 of the display device 10 where the data line DL is located. Accordingly, the first line layer VSL1 of the common power line VSL may not overlap with the data line DL in the first edge area EDA1. For example, the common power line VSL and the data line DL may not overlap each other in the thickness direction (e.g., third direction DR3) of the substrate SUB.

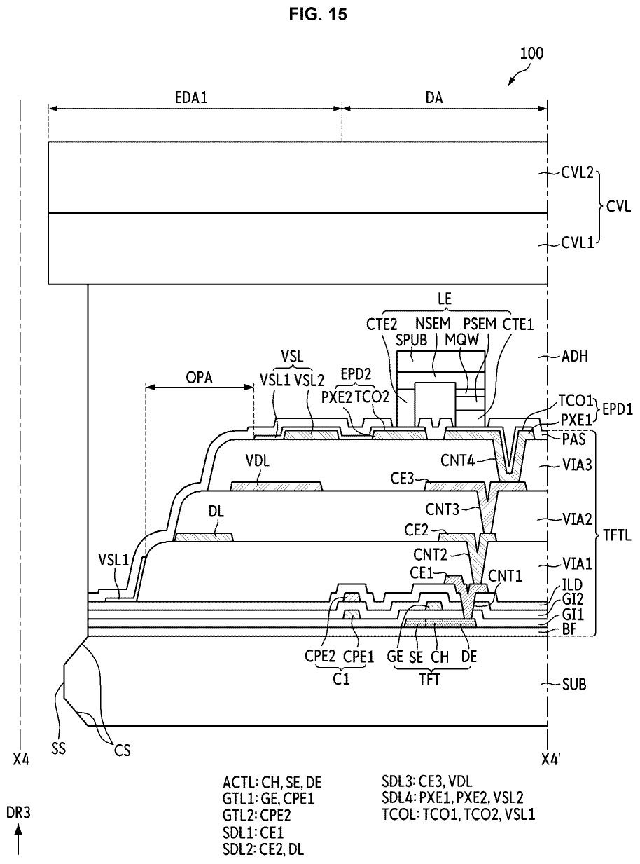

FIG. 15 is a cross-sectional view showing a display panel according to one or more embodiments of the present disclosure. For example, FIG. 15 shows a cross-section of a part of the display panel 100 taken along the line X4-X4′ of FIG. 10. The positions of the data line DL and the common power line VSL of FIG. 15 may be different from those of FIG. 14.

Referring to FIG. 15, the data line DL may be located closer to the edge of the second planarization layer VIA2. For example, the data line DL may be substantially in close contact with the edge of the second planarization layer VIA2. For example, as the width of the first edge area EDA1 is reduced or minimized, the data line DL may be closer to the end of the first edge area EDA1 where the second planarization layer VIA2 and the like are terminated. Alternatively, the data line DL may be substantially attached to the edge of the second planarization layer VIA2 due to a scratch or process error.

Accordingly, the data line DL may not be completely or properly covered by the second planarization layer VIA2. For example, the left edge of the data line DL may be exposed without being covered by the second planarization layer VIA2, or the thickness of the second planarization layer VIA2 covering the left edge of the data line DL (e.g., the side surface of the data line DL) may become very thin.

If a line is located on the edge of the data line DL and/or the second planarization layer VIA2 where the second planarization layer VIA2 does not properly cover the data line DL, there is a risk of short circuit between the line and the data line DL. In view of the above, according to the embodiments, a part of the first line layer VSL1 of the common power line VSL located closer to the end of the display panel 100 than the data line DL is opened in the first edge area EDA1, so that it is possible to reduce or prevent the likelihood of short circuit defects between the data line DL and the common power line VSL. In this manner, it is possible to reduce the non-display area including the first edge area EDA1 without creating a short circuit between the lines.

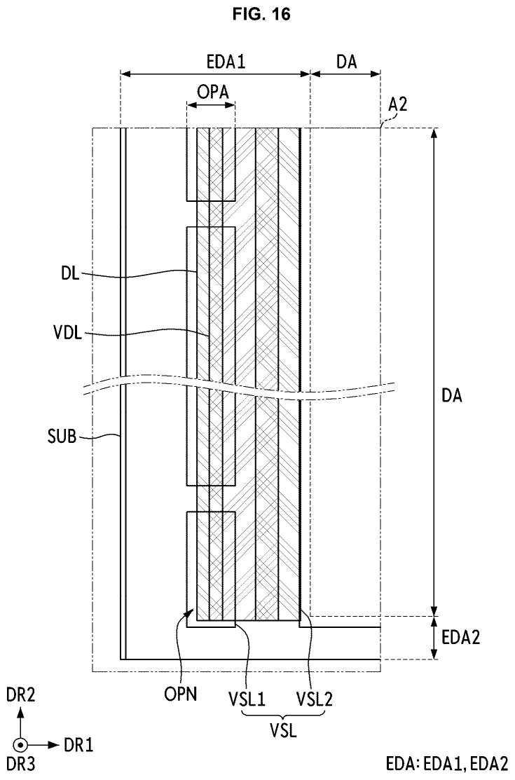

FIG. 16 is a plan view showing lines located at an edge of a display device according to one or more embodiments. For example, FIG. 16 shows an example of lines that may be located in area A2 of FIG. 8.

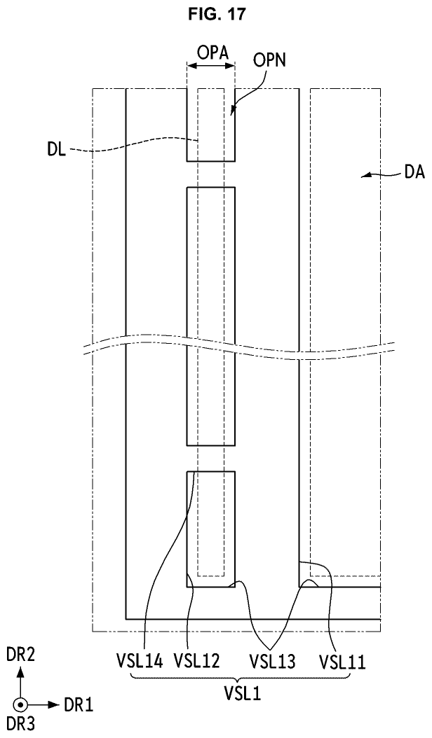

FIG. 17 is a plan view showing a first line layer of a common power line according to one or more embodiments. For example, FIG. 17 shows the first line layer VSL1 of the common power line VSL shown in FIG. 16.

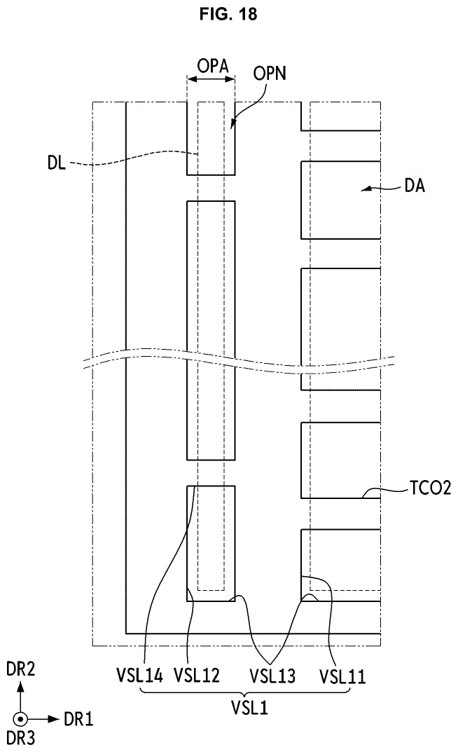

FIG. 18 is a plan view showing a first line layer of a common power line according to one or more embodiments. For example, FIG. 18 shows another example of the first line layer VSL1 of the common power line VSL shown in FIGS. 16 and 17.

Referring to FIGS. 16 to 18, the first line layer VSL1 of the common power line VSL may further include a fourth portion VSL14 (also referred to as a fourth line portion) in addition to a first portion VSL11, a second portion VSL12, and a third portion VSL13. For example, the first line layer VSL1 of the common power line VSL may include a plurality of fourth portions VSL14. The first portion VSL11, the second portion VSL12, and the third portion VSL13 have been described in the embodiments of FIGS. 10 to 12, and thus will not be described in detail.

The fourth portion VSL14 of the first line layer VSL1 may be located in the first edge area EDA1 of the display device 10. For example, the fourth portion VSL14 of the first line layer VSL1 may traverse the opening OPN (or the open area OPA where the opening OPN is located) of the first line layer VSL1 in the first edge area EDA1, and may connect the first portion VSL11 with the second portion VSL12 of the first line layer VSL1. According to one or more embodiments of the present disclosure, the fourth portion VSL14 of the first line layer VSL1 may be formed integrally with the first portion VSL11 and the second portion VSL12 of the first line layer VSL1.

According to one or more embodiments of the present disclosure, the fourth portion VSL14 of the first line layer VSL1 may extend substantially in the first direction DR1 and cross the data line DL. By adjusting the width, position or number of the fourth portions VSL14 of the first line layer VSL1, the fourth portions VSL14 of the first line layer VSL1 can be formed where short circuit defects between the fourth portions VSL14 of the first line layer VSL1 and the data line DL can be avoided.

For example, the fourth portions VSL14 of the first line layer VSL1 may be formed such that they are spaced apart from one another by a distance (e.g., predetermined distance) or more where the risk of short-circuit defects due to scratches or process errors is relatively low. For example, the fourth portions VSL14 of the first line layer VSL1 may be formed such that they are spaced apart from one another by a distance (e.g., predetermined distance) or more in the upper edge area and the lower edge area (e.g., the second edge area EDA2) of the display device 10.

Accordingly, the area of the first line layer VSL1 of the common power line VSL can be increased to lower the resistance, while reducing or preventing the likelihood of a short circuit between the common power line VSL and the data line DL.

In the foregoing descriptions with reference to FIGS. 10 to 18, the embodiments of the edge area EDA of one of the display devices 10 included in the tiled display TIDS have been disclosed. For example, FIGS. 10 to 18 show the embodiments of the edge area EDA of one display device 10 that is located at the edge of the tiled display TDIS in the first direction DR1 and/or the second direction DR2 among the display devices 10 included in the tiled display TIDS. It should be understood, however, that the structure of the edge area EDA of the display device 10 described in the embodiments of FIGS. 10 to 18 is not limited only to the display device 10 located at the edge of the tiled display TDIS. For example, at least one display device 10 included in the tiled display TIDS may have a structure according to at least one of the embodiments of FIGS. 10 to 18. For example, a plurality of display devices 10 forming the tiled display TIDS may have substantially the same structure.

According to the above-described embodiments, it is possible to effectively reduce or prevent the likelihood of short circuit defects between lines that may occur at the edge area EDA of the display device 10. For example, according to the embodiments, a part of the common power line VSL may be opened above the data line DL located in the first edge area EDA1 of the display device 10. According to one or more embodiments of the present disclosure, the common power line VSL may include the first line layer VSL1 extended to the border of the first edge area EDA1, and the first line layer VSL1 may include at least one opening OPN in an open area OPA including an area where the first data line DL at the outermost position (or the laser data line DL) among the data lines DL connected to the pixels PX are located.

In the display devices 10 according to the embodiments and the tiled display TDIS including the same, it is possible to reduce or prevent the likelihood of short circuit defects between the common power line VSL and the data line DL. For example, even if the data line DL is not properly covered by an overlying insulating layer (e.g., the second planarization layer VIA2) due to process margins or scratches, as the common power line VSL is opened on the data line DL, it is possible to reduce or prevent the likelihood of a short circuit between the common power line VSL and the data line DL. As an example, even if a part of the data line DL is exposed or at least a part of the data line DL is cover with the insulating layer having an insufficient thickness for ensuring electric stability due to reduced process margin applied to the first edge area EDA1 or a scratch occurring in the first edge area EDA1, the common power line VSL is not located directly on the data line DL, so that there is formed no short circuit between the data line DL and the common power line VSL.

Although the embodiments disclose the structure and method for reducing or preventing the likelihood of short circuit defects between the common power line VSL and the data line DL, the embodiments are not limited to particular types of lines. For example, at least one of the common power line VSL and/or the data line DL may be replaced with other types of power line or signal line. In addition, to reduce or prevent the likelihood of short circuit defects between lines, electrodes, and/or conductive patterns located at the outermost positions in at least one edge area EDA of the display device 10, an opening may be formed in at least one line, electrode, and/or conductive pattern where the lines, electrodes, and/or conductive patterns overlap one another. According to embodiments, electrical stability of the display device 10 and the tiled display TDIS including the same can be ensured and the reliability can be increased.

In concluding the detailed description, those skilled in the art will appreciate that many variations and modifications can be made to the embodiments without substantially departing from the principles of the present disclosure. Therefore, the disclosed embodiments are used in a generic and descriptive sense only, and not for purposes of limitation.

What is claimed is:

1. A display device comprising:
a substrate comprising a display area, and a first edge area at one side of the display area;
a pixel above the substrate in the display area;
a data line in a first conductive layer above the substrate in the first edge area; and
a common power line comprising a first line layer in a second conductive layer above the substrate in the first edge area, the first line layer comprising:
a first portion between the display area and the data line; and
a second portion spaced from the first portion in a first direction to define an opening therebetween, the opening overlapping the data line.

2. The display device of claim 1, wherein the first edge area extends in a second direction crossing the first direction, and
wherein the first portion, the second portion, and the data line extend in the second direction.

3. The display device of claim 2, wherein the substrate further comprises a second edge area that meets the first edge area at an end of the first edge area, and that extends in the first direction, and
wherein the first line layer further comprises a third portion connecting the first portion with the second portion in the second edge area.

4. The display device of claim 3, wherein the third portion extends in the first direction.

5. The display device of claim 2, wherein the first line layer further comprises a fourth portion connecting the first portion with the second portion across the opening in the first edge area.

6. The display device of claim 1, wherein the pixel comprises a sub-pixel comprising:
a pixel circuit comprising a thin-film transistor; and
a light-emitting element connected to the pixel circuit.

7. The display device of claim 6, wherein the sub-pixel further comprises:
connection electrodes in source conductive layers above the thin-film transistor;
a first electrode pad above the connection electrodes, and connected between the connection electrodes and a first contact electrode of the light-emitting element; and
a second electrode pad above the connection electrodes, and connected between the common power line and a second contact electrode of the light-emitting element.

8. The display device of claim 7, wherein the first conductive layer is one of the source conductive layers, and
wherein one of the connection electrodes and the data line are in a same layer.

9. The display device of claim 8, wherein the first electrode pad comprises a first pixel electrode above the connection electrodes, and a first transparent electrode above the first pixel electrode, and
wherein the second electrode pad comprises a second pixel electrode above the connection electrodes apart from the first pixel electrode, and a second transparent electrode above the second pixel electrode.

10. The display device of claim 9, wherein the second conductive layer is a transparent conductive layer in which the first transparent electrode and the second transparent electrode are located, and
wherein the first line layer, the first transparent electrode, and the second transparent electrode are in a same layer.

11. The display device of claim 10, wherein the first line layer and the second transparent electrode are integral with each other.

12. The display device of claim 9, wherein the common power line further comprises a second line layer below the first line layer, and overlapping the first portion of the first line layer.

13. The display device of claim 12, wherein the second line layer, the first pixel electrode, and the second pixel electrode are spaced apart in a same layer.

14. The display device of claim 1, wherein the second conductive layer is above the first conductive layer.

15. The display device of claim 14, further comprising a planarization layer between the first conductive layer and the second conductive layer, and covering the first conductive layer.

16. The display device of claim 15, wherein the planarization layer comprises an end covering the data line in the first edge area, and
wherein the opening of the first line layer is in an open area where the end of the planarization layer and the data line are located.

17. The display device of claim 1, wherein the first line layer does not overlap the data line in a thickness direction of the substrate.

18. The display device of claim 1, further comprising conductive layers above the substrate, and comprising the first conductive layer and the second conductive layer,
wherein the first conductive layer is at a top of the conductive layers, and comprises a transparent conductive material.

19. The display device of claim 1, wherein the second portion is between the data line and an end of the first edge area, and is at an outermost position of lines in the first edge area.

20. A tiled display comprising:
display devices, at least one of the display devices comprising:
a substrate comprising a display area, and a first edge area at one side of the display area;
a pixel above the substrate in the display area;
a data line in a first conductive layer above the substrate in the first edge area; and
a common power line comprising a first line layer in a second conductive layer above the substrate in the first edge area,
wherein the first line layer comprises:
a first portion between the display area and the data line; and
a second portion spaced from the first portion in a first direction to define an opening therebetween, the opening overlapping the data line.
